(19) United States
(12) Patent Application Publication
(10) Pub. No.: US 2025/0338635 A1
(43) Pub. Date: Oct. 30, 2025

(54) MOSAIC COVERGLASS FOR SPACE POWER MODULES

(71) Applicant: MICROLINK DEVICES, INC., Niles, IL (US)

(72) Inventors: Christopher Youtsey, Libertyville, IL (US); Martin Drees, Niles, IL (US)

(21) Appl. No.: 19/188,350

(22) Filed: Apr. 24, 2025

Related U.S. Application Data
(60) Provisional application No. 63/638,156, filed on Apr. 24, 2024.

(51) Int. Cl. H10F 19/80; H10F 19/35; H10F 71/00

(52) U.S. Cl. CPC H10F 19/80; H10F 19/35; H10F 71/1395

(57) ABSTRACT

A space power module (SPM) can include a plurality of solar cells, a plurality of interconnect elements, and a plurality of planar pieces of cover glass forming a mosaic sheet of cover glass overlaying light receiving surfaces of the plurality of solar cells. Each interconnect element can connect two adjacent solar cells of the plurality of solar cells and can be arranged in-plane relative to the two adjacent cells. The plurality of planar pieces of cover glass can cover at least portions of the plurality of interconnect elements.

### CROSS-REFERENCE TO RELATED APPLICATIONS

This application claims priority and the benefit of U.S. Provisional Application No. 63/638,156 titled “MOSAIC SPACE GLASS FOR SPACE POWER MODULES” and filed on Apr. 24, 2024, the content of which is incorporated herein by reference in its entirety.

### BACKGROUND

Space based solar cells are often individually encapsulated with a single sheet of cover glass (i.e., one sheet of cover glass per cell). For space applications, cover glass is meant to protect the solar cell from the effects of energetic radiation, e.g., electrons, protons and ultraviolet light, as well as atomic oxygen that can cause damage and degradation to space power modules (SPMs) or space solar panels.

Conventional cover glass materials used to encapsulate SPMs include ceria-doped borosilicate glass microsheet as well as fused silica. Conventionally, the cover glass is applied to individual solar cells, referred to as cover glass interconnected cells (CICs).

### SUMMARY

Embodiments taught herein enable and include flexible and lightweight space power modules (SPMs) that include multiple solar cells that are interconnected and encapsulated with a cover glass. It is desirable to have SPMs that leverage space-qualified encapsulation materials such as ceria-doped space glass. In the SPM, the cover glass extends over multiple interconnected solar cells, protecting the cells, interconnects and bypass diodes that are connected in parallel between neighboring solar cells. To minimize mass, the cover glass is often very thin, e.g., in the range of 100 to 150 microns thick. It is therefore quite fragile and can easily crack. This fragility is conventionally mitigated by applying the cover glass per cell in a CIC and using conventional Ge-based space solar cells having their growth substrate which are also often rigid and provide mechanical stability. Embodiments taught herein provide and enable thin film flexible solar cells that do not have the rigidity of conventional III-V solar cells that include a rigid growth substrate. Also, embodiments taught herein disclose and enable flexible and mechanically robust SPMs as well as encapsulation methods that enable SPMs that are flexible and mechanically robust. This SPMS and encapsulation methods taught herein enable applications such as roll-up solar arrays in which the SPMs are wrapped around a mandrel with a small radius, e.g., as low as 1-2 inches. The SPMs can also be bonded and can conform to curved surfaces.

In some embodiments, a space power module (SPM) can include a plurality of thin film solar cells secured to a flexible backing layer, a plurality of interconnect elements, and a plurality of planar pieces of cover glass overlaying a light receiving surface of each of the plurality of thin film solar cells. Each interconnect element can connect two adjacent thin film solar cells of the plurality of thin film solar cells and can be arranged in-plane relative to the two adjacent cells. The plurality of planar pieces of cover glass can cover at least portions of the plurality of interconnect elements.

In some embodiments, the plurality of planar pieces of cover glass can be secured to the light receiving surface of each of the plurality of thin film solar cells via adhesive.

In some embodiments, each thin film solar cell of the plurality of thin film solar cells can be covered by multiple planar pieces of cover glass.

In some embodiments, the plurality of planar pieces of cover glass can include a plurality of cover glass tiles overlaying the light receiving surface of each of the plurality of thin film solar cells. The plurality of cover glass tiles can have a square shape, a rectangular shape, a hexagonal shape or another suitable shape.

In some embodiments, the plurality of planar pieces of cover glass can include a plurality of cover glass strips overlaying the light receiving surface of each of the plurality of thin film solar cells. The plurality of cover glass strips can extend across a dimension of the space power module.

In some embodiments, the plurality of interconnect elements can provide in-plane strain relief.

In some embodiments, each interconnect element of the plurality of interconnect elements can have a respective serpentine-shaped portion. For each interconnect element of the plurality of interconnect elements, the respective serpentine-shaped portion can be arranged in-plane relative to thin film solar cells connected by the interconnect element.

Each thin film solar cell of the plurality of thin film solar cells can have a notched corner. The plurality of interconnect elements can be arranged within spaces corresponding to notched corners of the plurality of thin film solar cells.

In some embodiments, a method for encapsulating space power modules with cover glass can include cutting a sheet of cover glass into a plurality of pieces of cover glass, securing the pieces of cover glass to a space power module containing a plurality of solar cells, and removing a temporary substrate securing the plurality of pieces of cover glass as a mosaic sheet.

In some embodiments, the method can include securing the sheet of cover glass to the temporary substrate. The temporary substrate can include a temporary adhesive substrate for securing the sheet of cover glass as a mosaic sheet to facilitate securing the mosaic sheet of cover glass to a plurality of SPMs. Cutting the sheet of cover glass into a plurality of pieces of cover glass to form a mosaic sheet of cover glass can include cutting the sheet of cover glass while the sheet of cover glass is bonded to the temporary adhesive substrate.

In some embodiments, securing the pieces of cover glass to the space power module can include bonding the pieces of cover glass, for example, as a mosaic sheet to the space power module using adhesive.

In some embodiments, cutting the sheet of cover glass into a mosaic sheet can include using a laser or a mechanical scribe.

In some embodiments, cutting the sheet of cover glass into a mosaic sheet can include cutting the sheet of cover glass into a plurality of tiles.

In some embodiments, cutting the sheet of cover glass into a mosaic sheet can include cutting the sheet of cover glass into a plurality of strips.

In some embodiments, the SPM can include a plurality of in-plane interconnect elements and the plurality of pieces of cover glass can cover the plurality of in-plane interconnect elements.

In some embodiments, each solar cell of the plurality of solar cells can be covered by multiple pieces of cover glass.

Each solar cell of the plurality of solar cells can have a notched corner. The plurality of interconnect elements can be arranged within spaces corresponding to notched corners of the plurality of solar cells.

### BRIEF DESCRIPTION OF DRAWINGS

The following drawings form part of the present specification and are included to further demonstrate certain features of the present disclosure. In the drawings, like reference characters generally refer to like features (e.g., functionally similar or structurally similar elements). The disclosure may be better understood by reference to one or more of these drawings in combination with the detailed description of embodiments presented herein.

FIG. 1 is a cross-sectional view of a pair of interconnected solar cell assemblies of a prior art space power module (SPM).

FIG. 2 illustrates a SPM having a 2×2 array of solar cells encapsulated with a mosaic sheet of linear cover glass tiles, according to an example taught herein.

FIG. 3 depicts the high flexibility of the SPM of FIG. 1 facilitated by the glass tiles, according to an example taught herein.

FIG. 4 illustrates a two-dimensional matrix or mosaic sheet of cover glass supported by a temporary substrate, according to an example taught herein.

FIG. 5 illustrates the SPM encapsulated with the two-dimensional matrix or mosaic sheet of cover glass of FIG. 4, according to an example taught herein.

FIGS. 6A and 6B illustrates a top view of in-plane interconnect elements connecting adjacent solar cells, according to an example taught herein.

FIG. 7 illustrates the SPM under forward bias to trigger the electroluminescence of the solar cells, according to an example taught herein.

FIG. 8 illustrates a roll-up solar array, according to an example taught herein.

FIG. 9 is a flowchart of a method for encapsulating an entire SPM with a cover glass mosaic sheet, according to an example taught herein.

### DETAILED DESCRIPTION

As used herein, space or outer space or outside of the earth's atmosphere refer to the area or regions that are beyond the Karman line, which is about 100 km above sea level.

As used herein, a solar power module (SPM) refers to an assembly of connected solar cells or a self-contained photovoltaic (PV) unit including a plurality of inter-connected solar cells that is mounted or to be mounted within a spacecraft or satellite. The SPM includes a top encapsulation to protect the solar cells and may include a backside or bottom encapsulation. The SPM is designed to generate electrical power from solar energy. A plurality of SPMs can be interconnected to create one or more larger solar arrays for power generation in the spacecraft or satellite.

Embodiments taught herein address various technical challenges associated with deploying and using SPMs in spacecrafts or satellites in the outer space. Specifically, to address challenges related to the fragility and flexibility of solar panels for space applications, a SPM can be encapsulated entirely with a mosaic sheet of a plurality of pieces of glass. The approach taught herein of encapsulating the SPM with a plurality of pieces of glass can be referred to herein as “mosaic coverglass” and facilitates flexibility to the SPM. In particular, using a plurality of appropriately sized pieces of cover glass, e.g., planar pieces, to encapsulate the SPM facilitates bending of the SPM along at least one dimension of the SPM. Dividing the full surface area of the SPM module into smaller areas each of which is covered by a corresponding piece of cover glass facilitates the SPM to flex or bend at the interfaces between the pieces of cover glass. Also, relatively small pieces of cover glass are less susceptible to cracking than a single, large piece of cover glass.

Satellites and spacecrafts operating in the inner solar system rely on solar panels as a power source. However, the outside of the earth's atmosphere presents various technical challenges with respect to using of solar panels as a power source. For example, significant energetic radiation and extremes of heat and cold outside the earth's atmosphere present serious hazards to space power modules (SPMs) and can cause serious damage or degradation to solar cells of solar panels. As a means of protection from the hazards encountered in the earth's atmosphere, SPMs taught herein are entirely encapsulated or covered using appropriately sized pieces of cover glass. The use of cover glass to encapsulate and protect solar cells increases the efficiency of the solar cells by minimizing or reducing the amount of light reflected at the encapsulation layer. The SPM can be fully encapsulated with the plurality of pieces of cover glass covering the full extent of the SPM to provide full protection of the SPM from hazardous environmental factors.

The use of relatively small or properly sized pieces of cover glass to form a mosaic as taught herein, lessens the susceptibility of the cover glass to cracking compared to a single sheet of cover glass or relatively large pieces of cover glass. Also, in the event that a piece of cover glass cracks or becomes damaged, the breakage is constrained to the individual piece of glass and does not propagate across the full SPM. Therefore, the use of a mosaic of a plurality of pieces of cover glass to encapsulate the SPM provides enhanced protection for the SPM and mitigates the effect of any damage to a local surface area of the SPM.

Another technical challenge is the limited space available for transporting solar panels outside the earth's atmosphere. In particular, NASA no longer has space shuttles to transport devices into space and solar panels have to be fit inside the front half of a rocket. Fitting relatively large solar panels into a space or volume of a launch vehicle is serious technical challenge. Besides the limited space, launch vehicles also impose limitations on the weight of solar panels. Specifically, minimizing or reducing the weight of the SPMs reduces the total weight carried by the launch vehicle.

The compactness of available tubular space for transporting solar panels to the outside of the earth's atmosphere brings the need for flexible solar arrays. However, the typically rigid nature of cover glass makes the manufacturing or building of flexible solar arrays technically challenging and costly. Flexible solar arrays can be folded or rolled up in a launch vehicle to achieve high levels of compactness during transportation. When released in space, the solar arrays can be open or expand to form a solar panel. The use of a mosaic cover glass or mosaic space glass as taught herein facilitates flexibility of the SPM. Specifically, the SPM can flex or bend along interfaces or gaps between the pieces of cover glass. Furthermore, the smaller are the pieces of cover glass the more flexible is the SPM.

The plurality of pieces of cover glass can be formed from one or more relatively large cover glass sheets. For example, one or more conventional cover glass sheets often used in space solar arrays can be divided into a plurality of pieces of cover glass that are used to encapsulate a SPM. The use of the mosaic cover glass as taught herein does not lead to an increase in the weight of the SPM. Furthermore, the increased resilience of the relatively small pieces of cover glass to cracks or damage due to environmental factors suggests that thinner cover glass sheets can be used leading to possible reduction in weight. As used herein, glass or cover glass refers to space glass, which includes but is not limited to ceria-doped borosilicate glass microsheet as well as fused silica. Those skilled in the art will appreciate that one or more alternatives to these examples of space glass or more generally to space glass are or may be available.

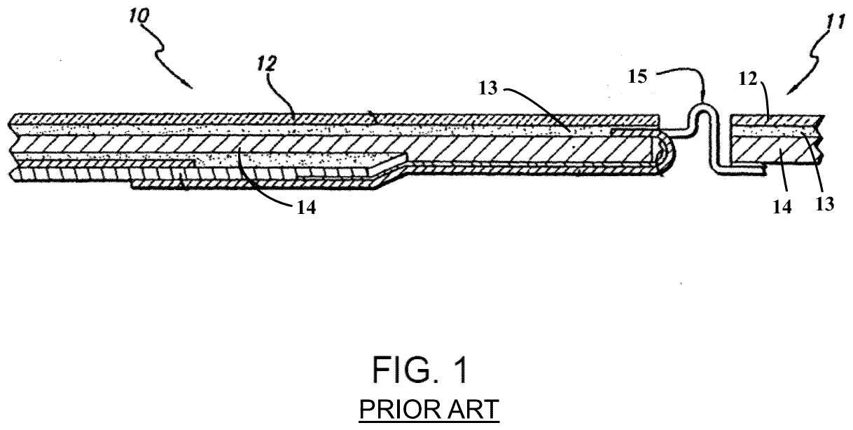

FIG. 1 is a cross-sectional view of a pair of interconnected solar cell assemblies 10 and 11 of a prior art SPM. Each of the solar cell assemblies 10 and 11 includes a solar cell 14 and a cover glass 12 disposed on a light receiving surface of the solar cell 14. The cover glass 12 is secured to the solar cell via adhesive 13. The two solar cells 14 are electrically connected via out-of-plane interconnects 15. While FIG. 1 shows a single interconnect 15, the two solar cells 14 are connected via three interconnects 15. Each of the interconnects 15 extends along a direction transverse or perpendicular to the solar cells 14 and the cover glass 12. The out-of-plane interconnects 15 extend beyond the light receiving surfaces of the solar cells 14. In other words, the out-of-plane interconnects 15 extend beyond the thickness of the solar cells 14 and rise above the light receiving surfaces of the solar cells 14.

Given the out-of-plane configuration of the interconnects 15, the interconnects 15 are not encapsulated or covered by the cover glass 12. Each solar cell 14 is covered by a single corresponding sheet of cover glass 12. The corresponding sheet of cover glass 12 is typically shaped and sized to have the shape and size of the light receiving surface of the solar cell 14 so that the side edges of the sheet of cover glass 12 aligns with the size edges of the solar cell 14 on which the sheet of cover glass 12 is disposed.

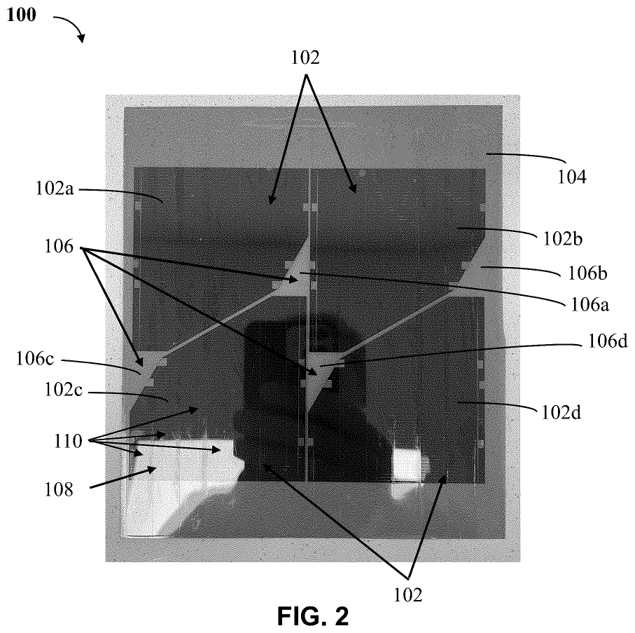

Referring now to FIG. 2 a SPM 100 having a 2×2 array of solar cells encapsulated with a mosaic sheet of cover glass 108 including a plurality of pieces of cover glass 110 is illustrated, according to an example taught herein. It is to be noted that the SPM 100 can have a 2×2, 2×3, 2×4, 2×5 or 2×10 array of solar cells. One skilled in the art will appreciate that the SPM 100 may have an array with other number(s) and/or arrangement(s) of solar cells 102. The SPM 100 illustrates the approach of encapsulating solar arrays with relatively small pieces of cover glass. In brief overview, the SPM 100 includes an array of four solar cells 102 arranged on a backing layer 104. Each of the solar cells 102 have a shape to provide an area or space 106 for placement of in-plane interconnections to an adjacent solar cell. For example, as illustrated in FIG. 2, the solar cells 102 can have a notched corner providing the solar cells 102 with a trapezoid-like shape. One skilled in the art will appreciate that other shapes are also possible. The array of four solar cells 102 of the SPM 100 cover an area of approximately 5×5 inches. The solar cells 102 are usually fabricated from circular wafers with a diameter equal to 150 mm. In some embodiments, the solar cells 102 can be made half-wafer solar cells, e.g., two Quartex cells put together. In some embodiments, the maximum size the solar cells 102 can be no larger than 75×150 mm.

The SPM 100 includes a plurality of spaces 106 for placing or hosting interconnect elements to electrically connect adjacent solar cells 102. For example, the solar cell 102a has a notched corner leading to a space 106a between the solar cells 102a and 102b to host interconnect elements for electrically connecting the solar cells 102a and 102b. The solar cell 102d has a respective notched corner resulting in the space 106d between the solar cells 102c and 102d to host interconnect elements for electrically connecting the solar cells 102c and 102d. A notched corner of the solar cell 102c leads to the space 106c that can host interconnect elements for electrically connecting the solar cell 102c to an electrode of the SPM 100. A notched corner of the solar cell 102b leads to the space 106b that can host interconnect elements for electrically connecting the solar cell 102b to another electrode of the SPM 100. The solar cells 102 can have other shape(s) compared to the shape depicted in FIG. 2. The shape(s) of the solar cells 102 can be designed in a way such that when the solar cells 102 are arranged in an array, spaces 106 are left between adjacent solar cells 102 to host interconnect elements.

The SPM 100 or the array of solar cells is fully encapsulated with a cover glass mosaic sheet 108 including a plurality pieces of cover glass 110. Specifically, the cover glass mosaic sheet 108 includes a plurality of strips 110 that are about 150 microns thick and about 1 cm wide. In some embodiments, the strips can be as narrow as 5 mm or as wide as 150 mm. The thickness of the cover glass or cover glass pieces 110 can be between 25 μm and 1 mm. The strips of cover glass 110 are arranged adjacent to one another and each strip of glass 110 extends along or across a full dimension of the SPM 100. The strips of glass 110 can be secured to the solar cells or respective light receiving surfaces. For example, the cover glass strips 110 can be bonded to the light receiving surfaces of the solar cells 102 via a transparent silicone adhesive. In some embodiments, other types of adhesive or other means for bonding, fixing, securing or attaching the strips of cover glass 110 to the solar cells 102 or the respective light receiving surfaces can be used. For example, a transparent tape can be used to bond, fix, secure or attach the strips of glass 110 to the light receiving surfaces of the solar cells 102.

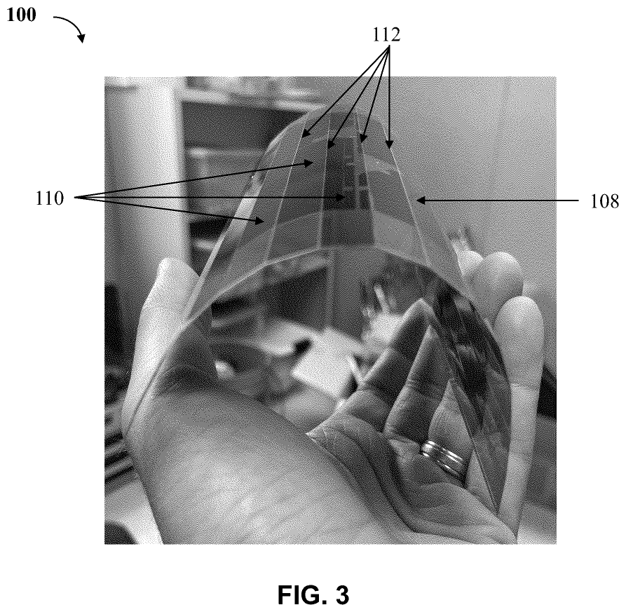

FIG. 3 illustrates the flexibility of the SPM 100 of FIG. 2 imparted by the use of a mosaic sheet of cover glass 108 of cover glass strips 110, according to an example taught herein. The use of a mosaic sheet of cover glass 108 of adjacent glass strips 110 to encapsulate the solar cells 102 leads to linear interfaces or linear interface regions 112 between adjacent strips of glass 110. The SPM 100 flexes or bends at or along the interfaces 112 between the strips of glass 110. As such, the SPM 100 is enabled to flex or bend across a direction transverse to an alignment direction of the strips of glass 110 or the interfaces 112 between the strips of glass 110. As described in U.S. Pat. No. 11,901,476, which is incorporated herein by reference in its entirety, can have a thickness of 10-50 μm, which allows for some flexibility while still providing support to the solar cells 102. In some embodiments, the backing layer 104 can be formed of a polymer, such as polyimide (PI) and/or KAPTON® among other types of polymer, which allow for some flexibility. In some embodiments, the backing layer 104 can be formed of metal, such as, but are not limited to, gold, copper, aluminum, titanium, platinum, silver, tungsten, and/or other alloys. In some embodiments the backing layer 104 can be a compound of metal and polymer. Those skilled in the art will appreciate that other embodiments may be possible. In some embodiments, the flexibility of the backing layer 104 can be achieved by using a relatively thin layer.

In embodiments where an adhesive, e.g., a transparent adhesive, is used to secure or bond the strips of cover glass 110 to the light receiving surfaces of the solar cells 102, the interfaces 112 between the strips of cover glass 110 can be filled with the adhesive. As such, the adhesive provides protection, from damaging environmental factors, to the SPM 100 along the interfaces 112. Also, the use of transparent adhesive reduces light reflection and/or light absorption along the interfaces 112 and therefore enables high performance of the solar cells 102.

The width of the strips of cover glass 110 can be selected or configured to be relatively small to increase or enhance resilience to cracks, breaking and/or other types of damage, and mitigate the effect of any potential damage. For example, the width of the strips of cover glass 110 can be selected or configured to be smaller than one or more dimensions of the solar cells 102 such that each solar cell 102 is covered by multiple strips of cover glass 110, as depicted in FIG. 2. During deployment, any damaged strip of cover glass 110 would mainly affect the performance of the region of the SPM 100 covered by the damaged strip with little or no degradation effect on other regions of the SPM 100.

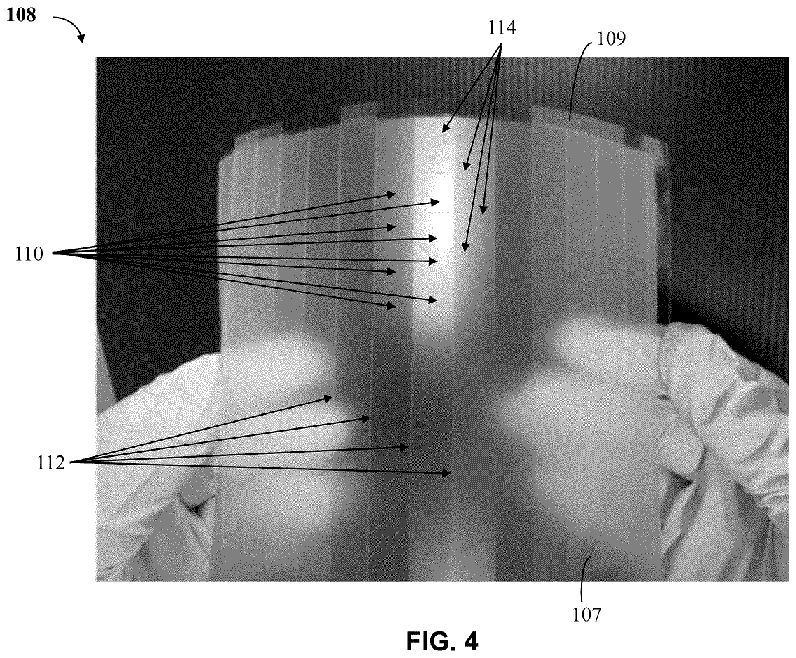

Referring now to FIG. 4, a two-dimensional matrix or mosaic sheet of cover glass 108 supported by a temporary adhesive substrate 109 is shown, according to an example taught herein. The mosaic sheet of cover glass 108 includes a plurality of pieces of cover glass 110. As discussed in further detail below, the cover glass mosaic sheet 108 can be formed by overlaying a sheet of cover glass 107 on the temporary adhesive substrate 109 and cutting, e.g., laser cutting, the sheet of cover glass 107 into a plurality of pieces 110, e.g., tiles, to form the two-dimensional matrix or mosaic sheet of cover glass 108. In general, the sheet of cover glass 107 can be cut into a plurality of pieces 110, e.g., planar pieces, of any shape(s) and/or size(s). For example, the sheet of cover glass 107 can be cut into a plurality of strips 110, e.g., as described in relation to FIGS. 2 and 3.

In some embodiments, the glass tiles 110 can be square shaped and can have a size of about 1 cm×1 cm. The size of 1 cm×1 cm can be selected to provide a desired amount of flexibility and/or to enable encapsulation of the entire SPM with a integer number of tiles or pieces 110. It is to be noted that the cover glass tiles 110 represent an example of one geometric shape, and as taught herein a mosaic sheet of cover glass 108 can have other shapes and/or other size(s) as long as the mosaic sheet of cover glass 108 extends past the light receiving surface of a cell to also cover or encapsulate the in-plane interconnections between adjacent solar cells in a SPM. For example, the cover glass tiles or pieces 110 can have triangular shape(s), square shape(s), rectangular shape(s), hexagonal shape(s) and/or octagonal shape(s) among other possible shapes. With regard to the size, the size of the cover glass tiles or pieces 110 can be selected, e.g., smaller than the size of a single solar cell 102 in an SPM 100, to enhance resilience to cracks, breaking and/or other types of damage, mitigate or localize the effect of any incurred damage to the damaged tile, and increase flexibility so long as the sheet of mosaic sheet of cover glass 108 extends past the light receiving surface of the cell to also cover or encapsulate the in-plane interconnections between adjacent solar cells 102 in the SPM 100. For example, the size of the cover glass tiles or pieces 110 can be selected based on a diameter of a mandrel or a dimension of a mandrel around which the corresponding SPM 100 is to be rolled. The use of the cover glass tiles 110 leads to first linear interfaces or first linear interface regions 112 along a first direction or dimension of the cover glass matrix or mosaic sheet 108 and second linear interfaces or second linear interface regions 114, along a second direction or dimension of the matrix or mosaic sheet of cover glass 108 transverse to the first direction or dimension, between adjacent pieces of glass 110. As such, the matrix or mosaic sheet of cover glass 108 can flex and/or bend at the interfaces 112 and/or the interfaces 114 leading to two degrees of freedom with respect to directions of flexibility.

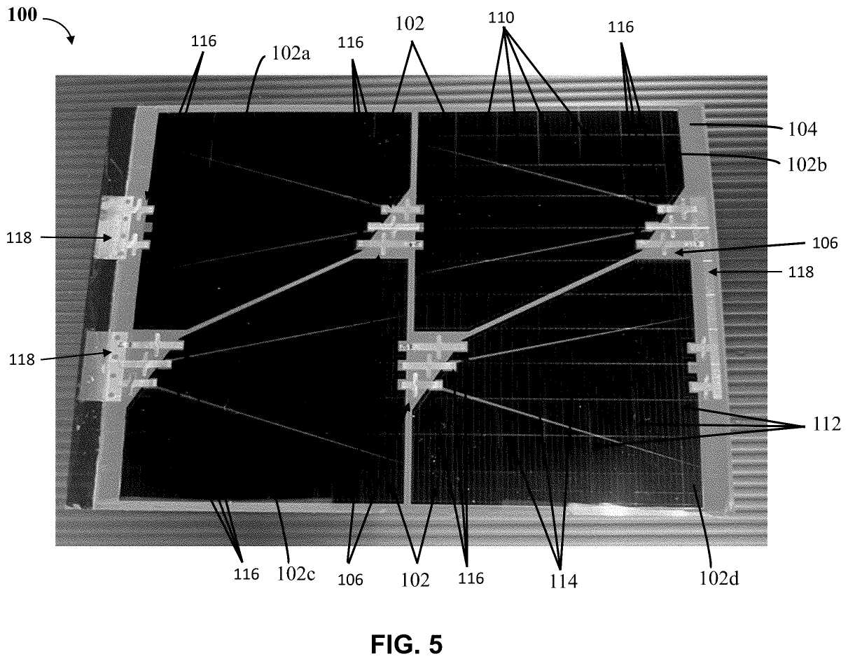

The strips and tiles of cover glass represent different examples of the pieces of cover glass 110 forming the mosaic sheet of cover glass 108. Similar to the strips of cover glass 110 in FIGS. 2 and 3, the glass tiles 110 of FIG. 4 can be overlaid on light receiving surfaces of the solar cells in a SPM, as described below in relation to FIG. 5. The cover glass tiles 110 can be bonded, fixed, secured and/or attached to the solar cells or the respective light receiving surfaces using adhesive, e.g., transparent silicone adhesive, tape and/or other bonding, fixing, securing and/or attachment means. Once the glass tiles 110 are bonded, fixed, secured and/or attached to the solar cells 102, the temporary adhesive substrate 109 can be removed.

FIG. 5 illustrates SPM 100 encapsulated with the two-dimensional matrix or mosaic sheet of cover glass 108 of FIG. 4, according to an example taught herein. While in FIGS. 2 and 3, the pieces of cover glass 110 encapsulating the SPM 100 are in the form of strips while the pieces of cover glass 110 encapsulating the SPM 100 in FIG. 5 are in the form of cover glass tiles 110. The cover glass mosaic sheet 108 and the respective cover glass tiles 110 of FIG. 4 are bonded, fixed, secured and/or attached to the solar cells 102 or the respective light receiving surfaces, e.g., using an adhesive or some other securing means.

The pieces of cover glass 110 can be made of different glass materials that include conventional space glass, e.g., ceria-doped borosilicate glass, fused silica, Corning Gorilla Glass, Willow Glass, Schott D263T, Schott AS87T and/or similar microsheet glass materials. The thickness of the pieces of glass can be as thin as 25 microns or as thick as 1000 microns. The pieces or planar pieces of cover glass 110, e.g., tiles, can have a square shape(s), a rectangular shape(s), a hexagonal shape(s), an octagonal shape(s), a circular shape(s) or some other shape(s). The cover glass tiles or pieces 110 of the SPM 100 can have the same shape or different shapes. The cover glass tiles or pieces 110 of the SPM 100 can have the same size or different sizes. The pieces of cover glass 110 can be shaped and/or sized such that each solar cell 102 of the plurality of solar cells 102 is covered by multiple pieces of cover glass 110.

The solar cells 102 are interconnected using in-plane interconnect elements 116 with in-plane strain relief. The in-plane interconnect elements 116 can be arranged in spaces 106 between adjacent solar cells 102. The adjacent solar cells 102a and 102b are interconnected via three in-plane interconnect elements 116, and the solar cells 102c and 102d are interconnected via three other in-plane interconnect elements 116. The SPM 100 includes other interconnect elements 116 connecting the solar cells 102 to electrodes 118 of the SPM 100. For example, solar cells 102a and 102c are connected to a pair of electrodes 118 on one side of the SPM 100, and solar cells 102b and 102d are connected to another electrode 118 on another side of the SPM 100. In some embodiments, the interconnect element 116 can include one or more bypass diodes. The interconnect elements 116 can be made of a conductive material and/or metal.

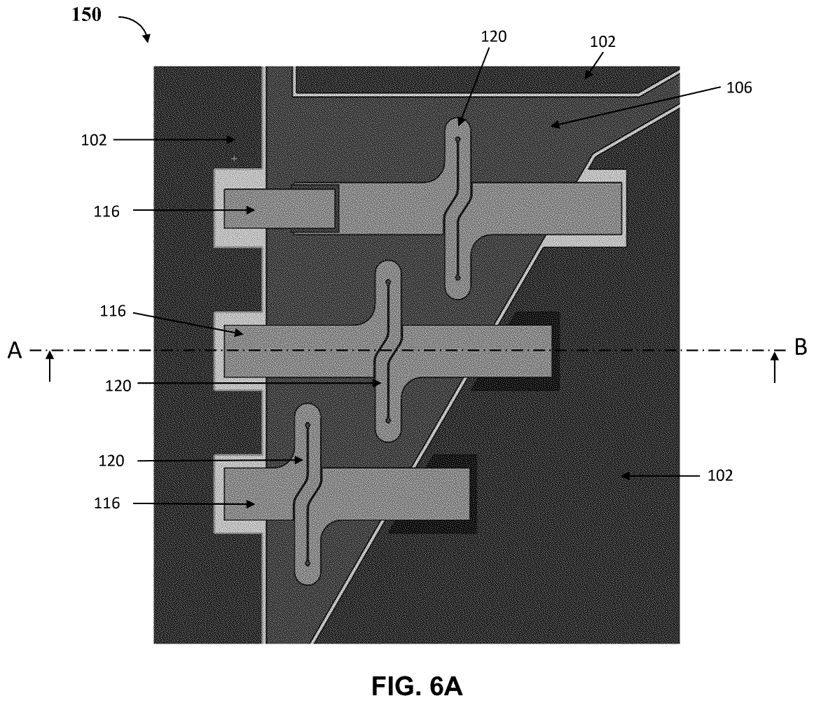

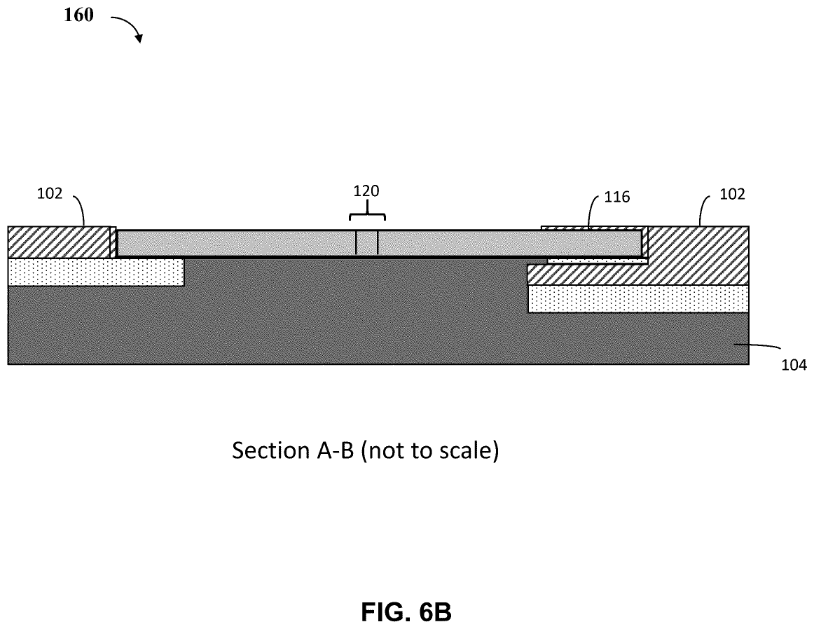

FIGS. 6A and 6B illustrate a top view 150 and a cross-sectional view 160 of the in-plane interconnect elements 116 connecting adjacent solar cells 102, according to an example taught herein. In particular, FIG. 6A illustrates the top view 150 and FIG. 6B illustrates the cross-sectional along the A-B axis depicted in FIG. 6A. Each in-plane interconnect element 116 can include a respective serpentine portion 120 arranged, configured and/or oriented along a plane parallel to the adjacent solar cells 102 or the corresponding light receiving surfaces. As the in-plane interconnect elements 116 contract and/or expand, the corresponding serpentine portions 120 remain in-plane relative to the adjacent solar cells 102. In particular, as the in-plane interconnect elements 116 contract and/or expand, e.g., due to change in environmental temperatures, the corresponding serpentine portions 120 remain oriented within the same plane parallel to the light receiving surfaces of the solar cells 102, or more generally stay confined within the space 106 defined by the side edges of the adjacent solar cells 102 and the top encapsulation by the cover glass mosaic sheet 108 or the respective pieces of cover glass 110, e.g., strips or tiles. In some embodiments, as the in-plane interconnect elements 116 contract and/or expand, the corresponding serpentine portions 120 or any other portion of the in-plane interconnect element 116 remains in-plane and does not change plane. It is to be noted that that the serpentine portions 120 can have a shape different from the one illustrated in FIG. 6. The serpentine portion 120 can include one or more in-plane loops, a zigzag shape, a sinusoidal shape or some other curved or wiggly shape to enable or facilitate strain relief while maintaining electrical connection.

Referring to FIG. 6B, the in-plane interconnect elements 116 can be structured or configured to be arranged in-plane relative to the light receiving surfaces of the solar cells 102. Specifically, the in-plane interconnect elements 116 are confined to space(s) or region(s) 116 between adjacent solar cells 102 and the cover glass pieces 110 or cover glass mosaic sheet 108 overlaying the light receiving surfaces of the solar cells 102. In other words, the in-plane interconnect elements 116 or any portion(s) thereof do not extend or do not extend significantly beyond or above the level of the light receiving surfaces of the solar cells 102. For example, the interconnect elements 116 or any portion(s) thereof may not protrude or extend beyond the light receiving surfaces of the solar cells 102 by more than 150 um. This would limit how close the cover glass or cover glass mosaic 108 can be placed relative to the solar cells 102 when secured, fixed or bonded to the solar cells 102, e.g., with silicone adhesive. The in-plane configuration of the interconnect elements 116 enables or facilitates encapsulation of the interconnect elements 116 and the solar cells 102 with the pieces of cover glass 110, or more generally the mosaic sheet of cover glass 108 as described herein. The interconnect elements 116 can be at least partially covered or encapsulated by the mosaic sheet of cover glass 108 or the respective pieces of cover glass 110. Each in-plane interconnect element 116 can be covered or encapsulated by one or more pieces of cover glass 116 and/or adhesive or other bonding means at the interfaces 112 and/or 114 between the pieces of cover glass 110.

The serpentine portions 120 of the in-plane interconnect elements 116 enable, provide or facilitate strain relief. For space applications in particular, it is important that the in-plane interconnect elements 116 incorporate strain relief that allows the in-plane interconnect elements 116 to expand and contract when placed under thermal stresses. Solar arrays in space can experience temperature extremes between −170 C and +160 C, with many repeated thermal cycles. Space solar cells frequently implement strain relief using out-of-plane loops or structures, e.g., as illustrated in FIG. 1, that are very space efficient. However, out-of-plane plane strain relief is not compatible with module-level encapsulation, in which a planar encapsulation is applied over an entire SPM including the respective solar cells and the respective interconnect elements. In other words, out-of-plane interconnect elements usually protrude, at least partially, above or beyond the light receiving surfaces of the solar cells therefore preventing entire planar encapsulation of the SPM.

The in-plane interconnect elements 116 of the SPM 100 can be structured, configured and/or oriented in-plane, e.g., relative to the solar cells 102 or the respective light receiving surfaces. For example, the serpentine portions 120 of the in-plane interconnect elements 116 can be arranged, positioned and/or oriented along a plane, e.g., parallel to light receiving surfaces of the solar cells 102. The in-plane arrangement, positioning and/or configuration of the serpentine portions 120 of the in-plane interconnect elements 116 enable or allow the in-plane interconnect elements 116 to contract and expand within the space 106 confined by the edges of the neighboring solar cells 102 and the mosaic sheet of cover glass 108 that provides a full top surface encapsulation of the SPM 100. In general, the in-plane interconnect elements 116 and/or respective serpentine portions 120 can be arranged, positioned, oriented, designed, shaped and/or sized to contract and expand without significantly protruding or extending beyond or above the light receiving surfaces of the solar cells 102, therefore enabling or providing in-plan strain relief with full top surface encapsulation of the SPM 100.

The use or implementation of in-plane strain relief often requires additional area or space to integrate, place, position and/or arrange the in-plane interconnect elements 116 or the respective serpentine portions 120. Normally this would require increasing the distance or spacing between the solar cells 102 to accommodate or integrate the in-plane interconnect elements 116. To avoid increased spacing between adjacent solar cells 102, the solar cells 102 can be designed, configured or shaped to leave or create open spaces or open regions, for example, a notched corner 106 between adjacent solar cells 102 to accommodate, place or integrate the cell-to-cell in-plane interconnect elements 116 or the cell-to-electrode in-plane interconnect elements 116, and therefore implement the in-plane strain relief with efficient use of the compact space defined by the SPM 100. The corner regions 106 can be V-shaped, triangular-shaped or can have other shape(s) or form(s). In some embodiments, each solar cell 102 can be connected to another solar cell 102 directly or indirectly for example, via an electrode 118 or a bypass diode.

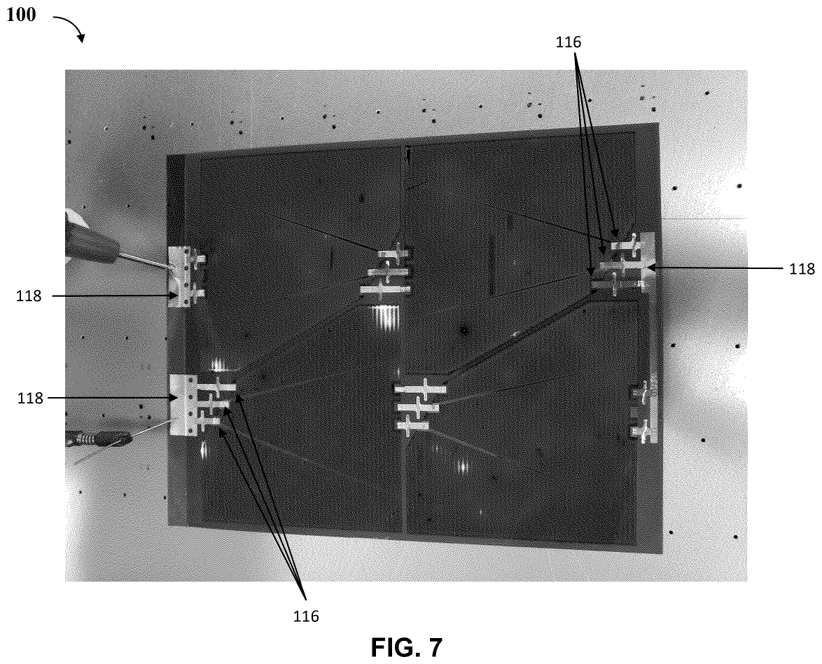

FIG. 7 shows the 2×2 SPM 100 of FIG. 5 under forward bias to trigger electroluminescence of the solar cells 102, according to an example taught herein. Forward bias refers to the condition where external voltage is applied to the electrodes 312 such that the potential barrier across the P-N junctions of bypass diodes is reduced, therefore facilitating the flow of majority carriers, electrons and holes, and increasing electric current. Electroluminescence (EL) is the emission of light by the solar cells 302 in response to the electric current. The EL shows that the SPM 300 and the corresponding solar cells 302 are functioning properly. While the electroluminescence may not be very visible in a grayscale figures, FIG. 7 depicts spots of the light (in white) indicative of the electrolumiscence.

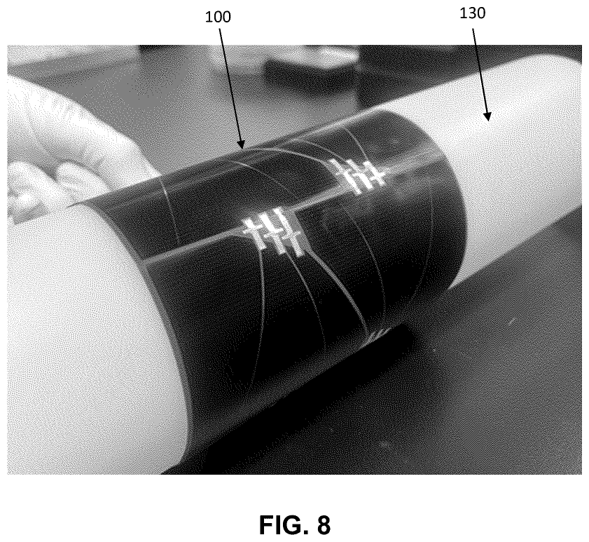

FIG. 8 illustrates the flexibility of the SPM 100, according to an example taught herein. The flexibility of the SPM 100 enables, allows or facilitates rolling or contouring the SPM 100 around a curved surface, for example, a mandrel 130, e.g., a cylindrical structure. As such, solar panels made of SPMs 100 can be rolled up before or during launch by a launch vehicle, and can be unrolled or opened upon reaching a desired orbit in space. The flexibility of the solar panels or the corresponding SPMs 100 can be adjusted, e.g., according to the size(s) and/or shape(s) of the pieces of glass 110 encapsulating the SPMs 100. For example, reducing the size of the pieces of cover glass 110, e.g., the dimensions of the cover glass tiles or the width of the cover glass strips, facilitates rolling up the SPMs 100 or the corresponding solar panel(s) around a mandrel 130 with a smaller radius, therefore, reducing the space occupied by the solar panel(s) within the launch vehicle.

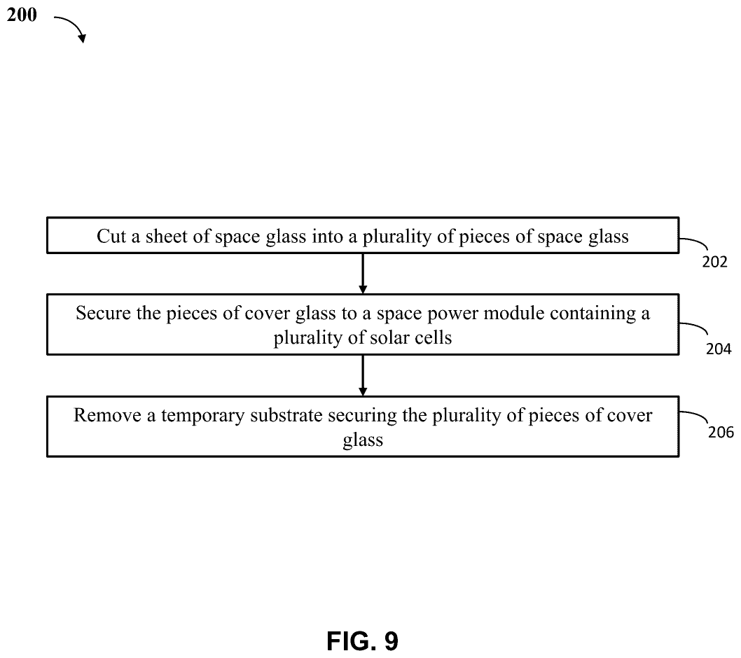

Referring now to FIG. 9, a flowchart of a method 200 for encapsulating an entire SPM with a cover glass mosaic sheet is shown, according to an example taught herein. In brief overview, the method 200 can include, at 202, cutting a sheet of cover glass (or space glass) into a plurality of pieces of cover glass to form a mosaic sheet of cover glass, securing at 204 the mosaic sheet of cover glass to a space power module containing a plurality of solar cells to encapsulate the entirety of the SPM including the interconnect elements, and removing the temporary substrate at 206. The SPMs and/or SPM 100 can be encapsulated or manufactured according to method 200.

The method 200 can include, at 202, cutting the sheet of cover glass 107 into a plurality of pieces of cover glass 110. Prior to cutting the sheet of cover glass 107, the method 200 can include overlaying the sheet of cover glass 107 on a temporary substrate. For example, the temporary substrate can include a temporary adhesive substrate or tape 109. Overlaying the sheet of cover glass 107 can include attaching the sheet of cover glass 107 to a sticky side of the temporary adhesive substrate or tape 109. In some embodiments, and as discussed further below, the use of the temporary substrate enables the sheet of cover glass to maintain substantially the same shape and/or geometry when cut into the plurality of pieces of cover glass 110.

Cutting the sheet of cover glass 107 into the plurality of pieces of cover glass 110 can include cutting the sheet of cover glass 107 while the sheet of cover glass 107 is bonded, fixed or secured to the temporary substrate, e.g., attached to the sticky side of the temporary adhesive substrate 109. As such, the pieces of cover glass 110 do not move relative to one another when cut and they maintain an overall shape and/or geometry similar to the shape or geometry of the sheet of cover glass 107 from which they were cut. In other words, when cut, the sheet of cover glass 107 is transformed into the mosaic sheet of cover glass 108. Also, having the cut pieces of cover glass 110 bonded, secured, fixed and/or attached to the temporary substrate facilitates the overlaying of the pieces of cover glass 110 on the surfaces, e.g., light receiving surfaces, of the solar cells 102. In particular, the fact that the cut pieces of cover glass 110 are bonded, secured, fixed and/or attached to the temporary substrate enables overlaying all the pieces of cover glass 110 at once, e.g., in a single step, action or move, on the surfaces of the solar cells 102.

Cutting the sheet of cover glass 107 can include using a laser, a mechanical scribe and/or other cutting processes or means known or will be known to a person skilled in the art. Cutting the sheet of cover glass 107 can include cutting the sheet of cover glass 107 into a plurality of tiles and/or cutting the sheet of cover glass 107 into a plurality of strips. The pieces of cover glass 110, e.g., tiles or strips, can have shape(s) and/or size(s) as discussed above. When cutting, the pieces of cover glass 110 can be shaped and/or sized such that each solar cell 102 of the plurality of solar cells 102 is covered by multiple cover glass pieces 110, e.g., multiple tiles and/or multiple strips of cover glass.

The method 20 can include, at 204, attaching, fixing, securing and/or bonding the pieces of cover glass 110 to the SPM 100 containing a plurality of solar cells 102. Attaching the pieces of cover glass 110 to the SPM 100 can include bonding the pieces of cover glass to the SPM 100 or the light receiving surfaces of the solar cells 102 using adhesive, e.g., transparent adhesive. For example, an adhesive layer can be placed on the light receiving surfaces of the solar cells 102. The pieces of cover glass 110, or the respective surfaces opposite to the surfaces attached to the temporary substrate, can then be placed on the light receiving surfaces of the solar cells 102 and/or the adhesive layer thereon. The adhesive layer can bond, secure, fix and/or attach the pieces of cover glass 110 to the surfaces, e.g., light receiving surfaces, of the solar cells 102. In some embodiments, the adhesive can be placed on the pieces of cover glass 110, e.g., instead of the light receiving surfaces of the solar cells 102, and then the pieces of cover glass 110 can be overlaid on the light receiving surfaces of the solar cells 102 to enable the adhesive to bond the pieces of cover glass to the light receiving surfaces of the solar cells 102. In some embodiments, a permanent adhesive substrate, tape or other bonding, securing, fixing and/or attachment means can be used to bond, secure, fix and./or attach the plurality of pieces of cover glass 110 to the light receiving surfaces of the solar cells 102.

The method 200 can include, at 206, removing the temporary substrate. In some embodiments, the temporary substrate can be maintained bonded, secured, fixed and/or attached to the pieces of cover glass 110 for a time period after overlaying the pieces of cover glass 110 on the light receiving surfaces of the solar cells 102 to allow the adhesive or other means to bond, secure, fix and/or attach the pieces of cover glass 110 to the light receiving surfaces of the solar cells 102 or to provide a protective layer. The adhesive and/or other bonding means can cover the interfaces, e.g., interfaces 112 and/or 114, between adjacent pieces of cover glass 110, therefore providing protection along such interfaces.

As discussed above, the SPM 100 can include a plurality of in-plane interconnect elements 116 and the plurality of cover glass pieces 110 can cover, at least partially, the plurality of in-plane interconnect elements 116. The in-plane interconnect elements 116 can be fully covered or encapsulated by the mosaic sheet of cover glass 108 or the plurality of cover glass pieces 110 e, e.g., together with any adhesive at the interfaces 112, 114.

In describing exemplary embodiments, specific terminology is used for the sake of clarity. For purposes of description, each specific term is intended to at least include all technical and functional equivalents that operate in a similar manner to accomplish a similar purpose. Additionally, in some instances where a particular exemplary embodiment includes a plurality of system elements, device components or method steps, those elements, components or steps may be replaced with a single element, component or step. Likewise, a single element, component or step may be replaced with a plurality of elements, components or steps that serve the same purpose. Moreover, while exemplary embodiments have been shown and described with references to particular embodiments thereof, those of ordinary skill in the art will understand that various substitutions and alterations in form and detail may be made therein without departing from the scope of the invention. Further still, other embodiments, functions and advantages are also within the scope of the invention.

1. A space power module (SPM) comprising:
a plurality of thin film solar cells;
a plurality of in-plane interconnect elements, each interconnect element connecting two adjacent thin film solar cells of the plurality of thin film solar cells and arranged in-plane relative to the two adjacent cells; and
a plurality of planar pieces of cover glass forming a mosaic sheet of cover glass overlaying a light receiving surface of each of the plurality of thin film solar cells, the mosaic sheet of cover glass covering at least portions of the plurality of interconnect elements.

2. The space power module of claim 1, wherein the plurality of planar pieces of cover glass are secured to the light receiving surface of each of the plurality of thin film solar cells via adhesive.

3. The space power module of claim 1, wherein each thin film solar cell of the plurality of thin film solar cells is covered by multiple planar pieces of cover glass.

4. The space power module of claim 1, wherein the plurality of planar pieces of cover glass includes a plurality of cover glass tiles overlaying the light receiving surface of each of the plurality of thin film solar cells.

5. The space power module of claim 4, wherein the plurality of cover glass tiles have a square shape, a rectangular shape or a hexagonal shape.

6. The space power module of claim 1, wherein the plurality of planar pieces of cover glass includes a plurality of cover glass strips overlaying the light receiving surface of each of the plurality of thin film solar cells.

7. The space power module of claim 6, wherein the plurality of cover glass strips extend across a dimension of the space power module.

8. The space power module of claim 1, wherein the plurality of interconnect elements provide in-plane strain relief.

9. The space power module of claim 1, wherein each interconnect element of the plurality of interconnect elements has a respective serpentine-shaped portion.

10. The space power module of claim 9, wherein for each interconnect element of the plurality of interconnect elements, the respective serpentine-shaped portion is arranged in-plane relative to thin film solar cells connected by the interconnect element.

11. The space power module of claim 1, wherein each thin film solar cell of the plurality of thin film solar cells has a notched corner and wherein the plurality of interconnect elements are arranged within spaces corresponding to notched corners of the plurality of thin film solar cells.

12. A method for encapsulating space power modules with cover glass, the method comprising:
cutting a sheet of cover glass into a plurality of pieces of cover glass to form a mosaic sheet of cover glass;
securing the mosaic sheet of cover glass to a space power module containing a plurality of solar cells; and
removing a temporary substrate securing the plurality of pieces of cover glass.

13. The method of claim 12, further comprising securing the sheet of cover glass to the temporary substrate.

14. The method of claim 13, wherein the temporary substrate includes a temporary adhesive substrate and securing the sheet of cover glass includes securing the sheet of cover glass to a sticky side of the temporary adhesive substrate.

15. The method of claim 14, wherein cutting the sheet of cover glass into a plurality of pieces of cover glass includes cutting the sheet of cover glass while the sheet of cover glass is secured to the sticky side of the temporary adhesive substrate.

16. The method of claim 12, wherein securing the pieces of cover glass to the space power module includes bonding the pieces of cover glass to the space power module using adhesive.

17. The method of claim 12, wherein cutting the sheet of cover glass includes at least one of:
using a laser or a mechanical scribe;
cutting the sheet of cover glass into a plurality of tiles; or
cutting the sheet of cover glass into a plurality of strips.

18. The method of claim 12, wherein the space power module includes a plurality of in-plane interconnect elements and the plurality of glass pieces cover the plurality of in-plane interconnect elements.

19. The method of claim 12, wherein each solar cell of the plurality of solar cells is covered by multiple cover glass pieces.

20. The method of claim 12, wherein each solar cell of the plurality of solar cells has a notched corner and wherein the plurality of interconnect elements are arranged within spaces corresponding to notched corners of the plurality of solar cells.
